(19) United States
(12) Patent Application Publication
(10) Pub. No.: US 2024/0251605 A1
(43) Pub. Date: Jul. 25, 2024

(54) DISPLAY PANEL AND MANUFACTURING METHOD THEREOF, AND DISPLAY APPARATUS

(71) Applicant: Visionox Technology Inc., Suzhou (CN)

(72) Inventors: Liusong NI, Suzhou (CN); Yiming XIAO, Suzhou (CN); Yuan YAO, Suzhou (CN); Xuejing ZHU, Suzhou (CN); Bowen YANG, Suzhou (CN); Haohan ZHANG, Suzhou (CN)

(73) Assignee: Visionox Technology Inc., Suzhou (CN)

(21) Appl. No.: 18/627,717

(22) Filed: Apr. 5, 2024

Related U.S. Application Data
(63) Continuation of application No. PCT/CN2023/108800, filed on Jul. 24, 2023.

(30) Foreign Application Priority Data
Aug. 2, 2022 (CN) 202210924882.5

(51) Int. Cl. H10K 59/122; H10K 59/12; H10K 59/35

(52) U.S. Cl. CPC H10K 59/122; H10K 59/1201; H10K 59/35

(57) ABSTRACT

A display panel and a manufacturing method thereof, and a display apparatus. In a first aspect, a display panel includes: a drive substrate; a pixel definition layer located on a side of the drive substrate, the pixel definition layer including a plurality of openings; a conductive layer located on a side of the pixel definition layer away from the drive substrate, the conductive layer including a plurality of conductive unit groups, the conductive unit group including at least two conductive units arranged spaced; a plurality of light-emitting devices, each of the light-emitting devices including a first electrode, a light-emitting functional layer and a second electrode sequentially stacked, the second electrode contacting with the conductive unit.

### CROSS REFERENCE TO RELATED APPLICATION

This application is a continuation of International Application No. PCT/CN2023/108800 filed on Jul. 24, 2023, which claims the priority benefits of Chinese Patent Application No. 202210924882.5 filed on Aug. 2, 2022 and entitled “Display Panel and Manufacturing Method thereof, and Display Apparatus”, both of which are incorporated herein by reference in their entireties.

### TECHNICAL FIELD

The application relates to the field of display technology, and in particular to a display panel and a manufacturing method thereof, a display apparatus.

### BACKGROUND

The organic light emitting diode (OLED) display panels, as flat display panels, are widely used in various consumer electronic products such as mobile phones, televisions, personal digital assistants, digital cameras, laptops, desktop computers, due to their advantages of high image quality, low power consumption, thin body and wide application range, and have become the mainstream of display panels.

However, the display panels in existing technologies have a problem of poor display effect.

### SUMMARY

The embodiments of the application provide a display panel and a manufacturing method thereof, and a display apparatus conducive to an improved display effect.

In a first aspect, the embodiments of the application provide a display panel including: a drive substrate; a pixel definition layer located on a side of the drive substrate, the pixel definition layer including a plurality of openings; a conductive layer located on a side of the pixel definition layer away from the drive substrate, the conductive layer including a plurality of conductive unit groups, and an orthographic projection of the conductive unit group onto the drive substrate being located between orthographic projections of adjacent openings onto the drive substrate, the conductive unit group including at least two conductive units arranged spaced; a plurality of light-emitting devices arranged in the plurality of openings respectively, each of the plurality of light-emitting devices including a first electrode, a light-emitting functional layer and a second electrode sequentially stacked in a direction away from the drive substrate, the second electrode contacting with the conductive unit.

Based on the same inventive concept, in a second aspect, the embodiments of the application provide a manufacturing method of a display panel, including:
providing a drive substrate;
forming a plurality of first electrodes spaced from each other on a side of the drive substrate;
forming a patterned pixel definition layer on a side of the drive substrate, the pixel definition layer including a plurality of openings exposing the first electrodes;
forming a patterned conductive layer on a side of the pixel definition layer away from the drive substrate, the conductive layer including a plurality of conductive unit groups, and an orthographic projection of the conductive unit group onto the drive substrate being located between orthographic projections of adjacent openings onto the drive substrate, the conductive unit group including at least two conductive units arranged spaced;
forming a light-emitting functional layer on a side of the first electrode away from the drive substrate, the light-emitting functional layers of different light-emitting devices being separated by the conductive units and the separation structure;
forming a second electrode on a side of the light-emitting functional layer away from the drive substrate, the second electrode contacting with the conductive unit.

Based on the same inventive concept, in a third aspect, the embodiments of the application provide a display apparatus including the display panel according to the embodiments of the first aspect.

### BRIEF DESCRIPTION OF THE DRAWINGS

Other features, objects and advantages of the application will become more apparent upon reading the following detailed description of non-limiting embodiments with reference to the accompanying drawings, in which the same or similar reference numerals refer to identical or similar features. The drawings are not drawn to actual scale.

FIG. 1 shows a schematic structural sectional view of a display panel provided by an embodiment of the application;

FIG. 2 shows a schematic top view of a local region of a display panel provided by an embodiment of the application;

FIG. 3 shows a schematic structural enlarged view of a region Q in FIG. 2;

FIG. 4 shows another schematic structural sectional view of a display panel provided by an embodiment of the application;

FIG. 5 shows yet another schematic structural sectional view of a display panel provided by an embodiment of the application;

FIG. 6 shows another schematic top view of a local region of a display panel provided by an embodiment of the application;

FIG. 7 shows yet another schematic top view of a local region of a display panel provided by an embodiment of the application;

FIG. 8 shows yet another schematic top view of a local region of a display panel provided by an embodiment of the application;

FIG. 9 shows yet another schematic top view of a local region of a display panel provided by an embodiment of the application;

FIG. 10 shows yet another schematic top view of a local region of a display panel provided by an embodiment of the application;

FIG. 11 shows a schematic flow chart of a manufacturing method of a display panel provided by an embodiment of the application;

FIGS. 12a to 12h show some schematic structural views corresponding to a manufacturing method of a display panel provided by an embodiment of the application;

FIGS. 13a to 13d show some other schematic structural views corresponding to a manufacturing method of a display panel provided by an embodiment of the application;

FIG. 14 shows a schematic structural view of a display apparatus provided by an embodiment of the application.

### LIST OF REFERENCE NUMBERS

10, drive substrate; 20, pixel definition layer; 30, conductive layer; 40, separation structure; 50, light-emitting device;
31, conductive unit; 41, first portion; 42, a second portion; 51, first electrode; 52, second electrode; 53, light-emitting functional layer; 531, hole injection layer; 532, hole transport layer; 533, organic light-emitting layer; 534, electron transport layer; 535, electron injection layer;
521, first sub-electrode; 522, second sub-electrode; 523, third sub-electrode;
501, first light-emitting device; 502, second light-emitting device; 503, third light-emitting device;
61, first film layer; 62, second film layer;
70, connection line; 71, first connection line; 72, second connection line;
711, first sub-connection line; 712, second sub-connection line; 713, third sub-connection line;
80, power bus; 81, first power bus; 82, second power bus; 83, third power bus.

### DETAILED DESCRIPTION

The features and embodiments of the application in various aspects will be described in detail below. For clearly understanding of the purpose, technical solution and advantages of the application, the application will be described in further details in combination with the drawings and specific embodiments. It should be noted that the specific embodiments described herein are configured to explain the application rather than to limit it. A person skilled in the art may implement the application without some of these specific details. The following description of the embodiments is for the purpose of better understanding of the application through showing examples of the application.

It should be noted that, in this context, the relational terms, such as first and second, etc., are used only to distinguish one entity or operation from another, and do not necessarily require or imply any such actual relationship or order between these entities or operations. Moreover, the terms “comprise”, “include”, or any other variation thereof are intended to encompass non-exclusive inclusion, so that a process, method, item or apparatus that includes a series of elements not only includes those elements, but also includes other elements that are not explicitly listed, or also includes elements inherent to such process, method, item or apparatus. Without further limitations, the elements limited by the wording “include” do not exclude the existence of further identical elements in the process, method item or apparatus that includes said elements.

It should be understood that in description of a structure of a component, when referring to a layer or region being located “on” or “above” another layer or region, it may refer to being directly located on top of the another layer or region, or containing a further layer or region between it and the another layer or region. Moreover, if the component is overturned, the layer or region will be located “under” or “below” the another layer or region.

It should be understood that the term “and/or” as used herein is merely to describe an association relationship of associated objects, meaning that there may be three relationship, for example, A and/or B may mean three cases that A exists alone, A and B exist simultaneously, and B exists alone. In addition, the character “/” herein generally indicates that the related objects before and after have an “or” relationship.

In the embodiments of the application, the term “connect” may refer to two components being directly connected, or may also refer to two components being connected via one or more further components.

It is obvious for a person skilled in the art that various modifications and changes may be made in the application without departing from the spirit or scope of the application. Therefore, the application is intended to cover the modifications and changes of the application that fall within the scope of the corresponding claims (technical solutions sough to be protected) and their equivalents. It should be noted that the implementations provided by the embodiments of the application may be combined with each other without contradiction.

The OLED display panels have many advantages such as self-illumination, fast response, high brightness and small thickness, and have gradually become the mainstream in the display field. The display panels in existing technologies have a problem of poor display effect.

In order to solve the above problem, the embodiments of the application provide a display panel and a manufacturing method thereof, and a display apparatus. The various embodiments of the display panel and the manufacturing method thereof, and the display apparatus will be described below in combination with the accompanying drawings.

The display panel provided by the embodiments of the application will be introduced below at first. The display panel provided by the embodiments of the application may be an OLED display panel.

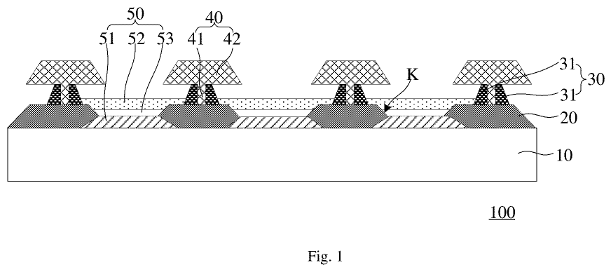

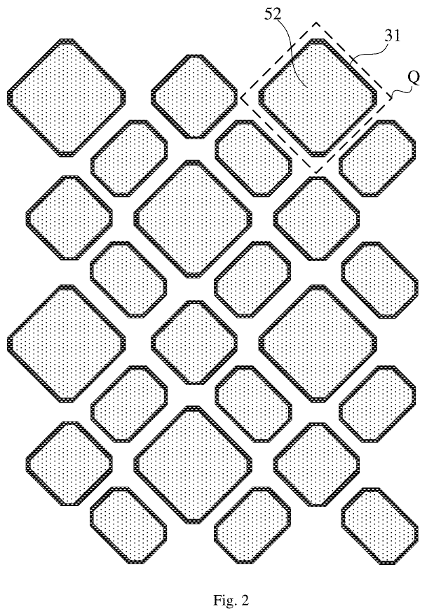

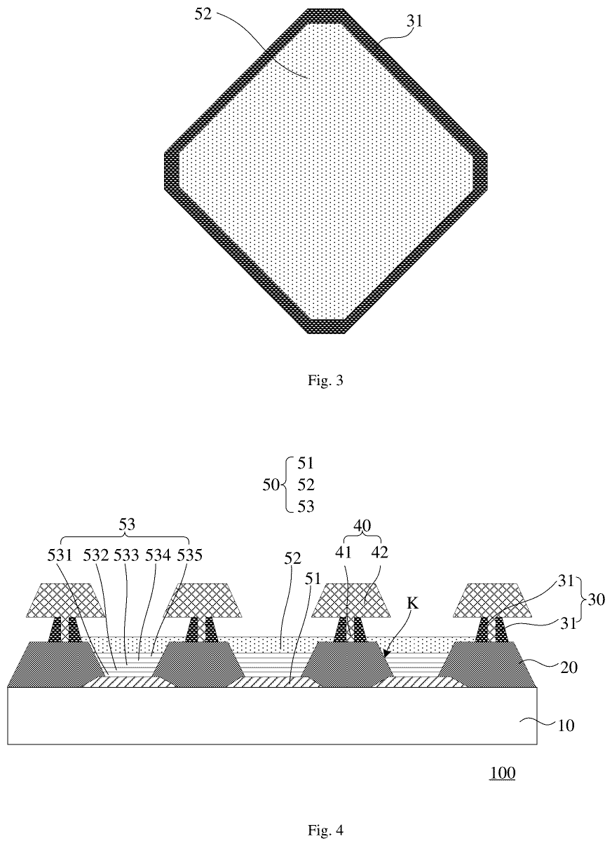

FIG. 1 shows a schematic structural sectional view of a display panel provided by an embodiment of the application. FIG. 2 shows a schematic top view of a display panel provided by an embodiment of the application. FIG. 3 shows a schematic structural enlarged view of a region Q in FIG. 2.

As shown in FIGS. 1 to 3, the display panel 100 provided by the embodiments of the application may include a drive substrate 10, a pixel definition layer 20, a conductive layer 30, and a light-emitting device 50.

The drive substrate 10 may include a drive circuit. For example, the drive substrate 10 may include a pixel drive circuit driving the light-emitting device 50 to emit light. The pixel drive circuit may be arranged in an array, and in this case, the drive substrate 10 may also be referred to as an array substrate. The pixel drive circuit may include devices such as transistors and capacitors. For another example, the drive substrate 10 may further include a signal wiring such as a scanning line and a data line.

The pixel definition layer 20 is located on a side of the drive substrate 10. The pixel definition layer 20 may include a plurality of openings K. The plurality of openings K may be arranged in an array. The openings of the pixel definition layer 20 may be used to define the position of the light-emitting device 50. The pixel definition layer 20 may include an inorganic material.

The conductive layer 30 is located on a side of the pixel definition layer 20 away from the drive substrate 10. The conductive layer 30 may include a plurality of conductive unit groups. An orthographic projection of the conductive unit group onto the drive substrate 10 may be located between orthographic projections of adjacent openings K onto the drive substrate 10. In particular, the conductive unit group includes at least two conductive units 31 arranged spaced. For example, the conductive unit 31 may be arranged to encircle at least one opening K.

It can be understood that the conductive unit 31 has electrical conductivity. The conductive unit 31 may include a metal material. The metal material may include but is not limited to Mo, Al, Ti, Cu and the like.

The light-emitting device 50 is arranged in the opening K of the pixel definition layer 20. A plurality of light-emitting devices 50 may be arranged in one-to-one correspondence with a plurality of openings K. The light-emitting device 50 may include a first electrode 51, a light-emitting functional layer 53 and a second electrode 52 stacked in a direction away from the drive substrate 10. The first electrode 51 may be an anode, and the second electrode 52 may be a cathode. The opening K of the pixel definition layer 20 exposes the first electrode 51. The pixel definition layer 20 may cover a part of an edge of the first electrode 51.

The second electrode 52 contacts with the conductive unit 31. The light-emitting functional layer 53 may contact with or may not contact with the conductive unit 31. It can be understood that the conductive unit 31 may encircle at least one second electrode 52. In the drawings of the application, as an example, the conductive units 31 are arranged in one-to-one correspondence with the openings K. In some further embodiments, the conductive unit 31 may also encircle a plurality of openings K, that is, the conductive unit 31 may encircle the second electrodes 52 of a plurality of light-emitting devices 50. As an example, the same conductive unit 31 may encircle the second electrodes 52 of a plurality of light-emitting devices 50 emitting light of the same color.

In the schematic top view of the display panel herein, in order to clearly illustrate the structure of the conductive layer 30, only the second electrode 52 of the light-emitting device 50 is illustrated, and other film layers of the light-emitting device 50 and some film layers of the display panel are hidden. It can be understood that one second electrode 52 in the schematic top view herein may be corresponding to one light-emitting device 50.

The conductive unit 31 is overall of an annular shape. Taking the example of various conductive units 31 separated from each other, the various second electrodes 52 are also separated from each other. In addition, the conductive unit 31 encircling the second electrode 52 does not necessarily indicate that the conductive unit 31 and the second electrode 52 are necessarily located in the same film layer, and the conductive unit 31 and the second electrode 52 may be located in different film layers. The same film layer can be understood as two components formed simultaneously by the same process step, and the different film layers can be understood as two components formed in steps by different process steps.

In the display panel provided by the embodiments of the application, the second electrode 52 contacts with the conductive unit 31, so that a drive signal can be supplied to each second electrode 52 by the conductive unit 31, thereby achieving the driving of the second electrode 52 easily.

The inventors have found by research that in order to reduce the process difficulty, some film layers in the OLED display panels (for example, the hole injection layer, the electron injection layer and the like) may be manufactured using a common mask plate for evaporation coating, and therefore, the film layers evaporation coated by a common mask plate are a continuous entire body (the film layers evaporation coated by a common mask plate are referred to as a common layer below), resulting in no true physical insulation formed between the sub-pixels of different colors, and when the sub pixels of various colors emit light, there will be lateral leakage between the sub-pixels via the common layer, which will also affect the display effect.

In order to solve the above problem, in some embodiments, as shown in FIG. 1, the display panel may also include a separation structure.

The separation structure 40 is an insulation structure. It can be understood that the separation structure 40 has no electrical conductivity. For example, the separation structure 40 may include an insulating material. The insulating material may include but is not limited to silicon nitride, silicon oxide and the like.

The separation structure 40 may include a first portion 41 and a second portion 42 connected to each other. The first portion 41 and the second portion 42 may be of an integrated structure, that is, during manufacturing, the first portion 41 and the second portion 42 may be formed integrally.

The first portion 41 is provided between at least a part of the adjacent conductive units 31 located in the same conductive unit group, and in particular, it can be understood as no openings K being provided between the conductive units 31 adjacent to the same first portion 41. It can be understood that the adjacent conductive units 31 may be spaced from each other by the first portion 41. For example, the display region of the display panel may include a plurality of sub-display regions. The adjacent conductive units 31 in the same sub-display region may contact with each other, while the conductive units 31 in different sub-display regions may be separated from each other by the first portion 41. In this case, without connection lines connecting the conductive units 31 in different sub-display regions, the conductive units 31 of different sub-display regions are independent of each other. For another example, the first portion 41 may be provided between any two adjacent conductive units 31. In this case, without connection lines connecting the different conductive units 31, any two conductive units 31 may be independent of each other.

The second portion 42 is located on a side of the conductive unit group away from the drive substrate 10, and an orthographic projection of the second portion 42 onto the drive substrate 10 covers an orthographic projection of the conductive unit group onto the drive substrate 10. That is, in a direction parallel to a light-emitting surface of the display panel, a width of the second portion 42 is greater than a width of the conductive unit group. The side surface consisting of the second portion 42 and the conductive unit 31 as a whole is not a flat surface. In the direction parallel to the light-emitting surface of the display panel, the side surface of the conductive unit 31 is closer to the first portion 41 than the side surface of the second portion 42.

FIG. 4 shows another schematic structural sectional view of a display panel provided by an embodiment of the application. As an example, as shown in FIG. 4, the light-emitting functional layer 53 may include a hole injection layer 531, a hole transport layer 532, an organic light-emitting layer 533, an electron transport layer 534 and an electron injection layer 535 stacked in the direction away from the drive substrate 10. Wherein at least one of the hole injection layer 531, the hole transport layer 532, the electron transport layer 534 and the electron injection layer 535 may be obtained by evaporation coating using a common mask plate. In addition, the second electrode 52 may also be obtained by evaporation coating using a common mask plate.

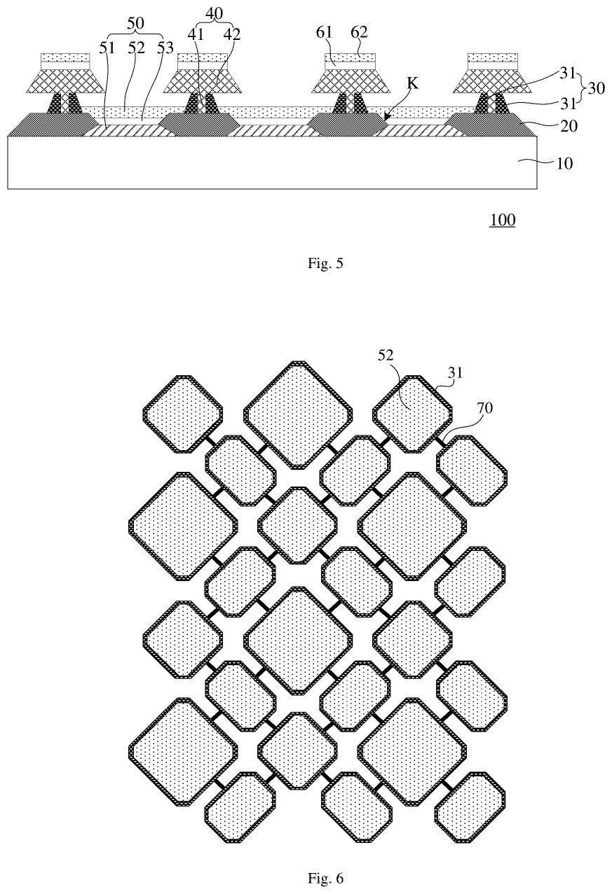

FIG. 5 shows yet another schematic structural sectional view of a display panel provided by an embodiment of the application. As shown in FIG. 5, in the case of using a common mask plate to form a part of the film layers of the light-emitting functional layer 53 (for example, at least one of the hole injection layer 531, the hole transport layer 532, the electron transport layer 534, and the electron injection layer 535), a first film layer 61 will be formed on a side of the separation structure 40 away from the drive substrate 10. Since the orthographic projection of the second portion 42 of the separation structure 40 onto the drive substrate 10 covers the orthographic projection of the conductive unit 31 onto the drive substrate 10, the first film layer 61 will be disconnected from the light-emitting functional layer 53, thereby achieving true physical insulation between the light-emitting functional layers 53 of different light-emitting devices 50. In the case of using a common mask plate to form the second electrode 52, a second film layer 62 will be formed on a side of the first film layer 61 away from the drive substrate 10. For the same reason, since the orthographic projection of the second portion 42 of the separation structure 40 onto the drive substrate 10 covers the orthographic projection of the conductive unit 31 onto the drive substrate 10, the second film layer 62 will be disconnected from the second electrode 52, thereby achieving separation between the second electrodes 52 of different light-emitting devices 50.

In the manufacturing process of the display panel, the first film layer 61 and the second film layer 62 may be further removed. Of course, the finished display panel may also retain the first film layer 61 and the second film layer 62, which is not limited by the application.

According to the embodiments of the application, since the orthographic projection of the second portion 42 onto the drive substrate 10 covers the orthographic projection of the conductive unit group onto the drive substrate 10, then the side surface consisting of the second portion 42 and the conductive unit group as a whole is not a flat surface, and in the direction parallel to the light-emitting surface of the display panel, the side surface of the conductive unit group is closer to the first portion 41 than the side surface of the second portion 42, so that true physical insulation can be achieved between the light-emitting functional layers 53 of different light-emitting devices 50 and the lateral leakage between different light-emitting devices 50 is reduced, thereby improving the display effect. In addition, the second electrodes 52 of different light-emitting devices 50 are separated from each other, which is conducive to providing different drive signals to the second electrodes 52 of different light-emitting devices 50, thereby facilitating dynamic adjustment of the potentials of different second electrodes 52, so that the power consumption of the display panel can be reduced.

It can be understood that the display region of the display panel includes a plurality of sub-display regions, and the adjacent conductive units in the same sub-display region are arranged in contact. Taking the conductive units in different sub-display regions being separated from each other by the first portion as an example, since the adjacent conductive units in the same sub-display region contact with each other, the second electrodes contact with the conductive units, that is, the second electrodes in the same sub-display region are connected to each other. According to the actual display situation, it is possible to provide different drive signals for the second electrodes in different sub-display regions, that is, zone control can be achieved, thereby facilitating dynamic adjustment of the potentials of the second electrodes in different sub-display regions, so that the power consumption of the display panel can be reduced.

In some optional embodiments, as shown in FIG. 6, the display panel may further include a connection line 70, and the connection line 70 may be connected to the conductive unit 31. The connection line 70 is a metal wiring, and due to the contact between the second electrode 52 and the conductive unit 31, the drive signals can be transmitted to the second electrode 52 by the connection line 70 and the conductive unit 31. In this way, by providing the connection line 70, the drive signals can be conveniently transmitted to the second electrode 52.

As an example, continuing to refer to FIG. 6, any two adjacent conductive units 31 may be connected to each other by a connection line 70. In this way, a plurality of second electrodes 52 of the entire display panel may be directly connected to each other, so that the drive signals can be provided conveniently to each second electrode 52.

As an example, a line width of the connection line 70 may be greater than or equal to 1.5 μm. The minimum line spacing between adjacent connection lines 70 may be greater than or equal to 2 μm. The minimum distance between the connection line 70 and the opening K may be greater than or equal to 1 μm.

A plurality of connection lines 70 may be located in the same film layer. The connection line 70 and the conductive unit 31 may be located in the same film layer. Or a plurality of connection lines 70 may be located in a plurality of film layers. For example, at least a part of the connection lines 70 may be arranged in the drive substrate 10.

As an example, at least a part of the different second electrodes 52 may be connected by the connection line 70 and the conductive unit 31. As an example, the display region of the display panel may be divided into a plurality of sub-display regions, and the second electrodes 52 of a plurality of light-emitting devices 50 in the same sub-display region may be connected by the connection line 70. In this way, zone control can be achieved, for example, it is possible to provide different potentials for the second electrodes of different sub-display regions according to actual display requirements.

As an example, the second electrodes 52 of all the light-emitting devices 50 in the same sub-display region may be connected by the connection line 70.

As an example, the display panel may include a plurality of power buses, the second electrodes of the light-emitting devices in the same sub-display region may be connected to the same power bus, and the second electrodes of the light-emitting devices in different sub-display regions may be connected to different power buses. In this way, according to the actual display situation, it is possible to use different power buses to provide different drive signals for the second electrodes in different sub-display regions so as to achieve zone control, thereby facilitating dynamic adjustment of the potentials of the second electrodes in different sub-display regions, so that the power consumption of the display panel is reduced.

The inventors have also found by research that the characteristics of the light-emitting devices of different colors are different. In the case that the second electrodes of the light-emitting devices of all colors of the display panel are connected to each other, in order to take the light-emitting devices of all colors into account, it is required to provide a relatively low voltage for the second electrodes, resulting in a higher power consumption of the display panel.

As an example, the display region of the display panel may include the light-emitting devices 50 of a plurality of colors, and the second electrodes 52 of the light-emitting devices 50 of the same color may be connected by the connection line 70. There may be no connection line provided between the second electrodes 52 of the light-emitting devices 50 of different colors. In this way, it is possible to provide drive signals of different potentials for the second electrodes 52 of the light-emitting devices 50 of different colors, without the need to provide a unified lower potential signal, which is conducive to reducing the power consumption of the display panel. For example, the display region of the display panel may be divided into a plurality of sub-display regions, and the second electrodes 52 of the light-emitting devices 50 of the same color in the same sub-display region may be connected by the connection line 70.

FIG. 7 shows yet another schematic top view of a local region of a display panel provided by an embodiment of the application. As another example, as shown in FIG. 7, a plurality of light-emitting devices 50 are arranged in a plurality of rows. The light-emitting device 50 includes the light-emitting devices of a plurality of colors, and the second electrodes 52 of the light-emitting devices 50 of the same color in the same row or column are connected to each other by the connection line 70. There may be no connection line provided between the second electrodes 52 of the light-emitting devices 50 of different colors. This can make the arrangement pattern of the connection lines 70 consistent with the arrangement pattern of other signal lines of the display panel (such as scanning signal lines, light-emitting control signal lines, initialization signal lines), which is conducive to improved display uniformity.

The second electrodes 52 of the same shape and the same area in the schematic top view herein may be corresponding to the light-emitting devices 50 of the same color. FIG. 7 illustrates three types of second electrodes 52 of roughly the same shape but different areas. It can be understood that FIG. 7 illustrates the light-emitting devices 50 of three colors.

As shown in FIG. 7, taking the direction X as a row direction and the direction Y as a column direction as an example, a part of the rows may include the light-emitting devices 50 of two colors, and a part of the rows may include the light-emitting devices 50 of one color.

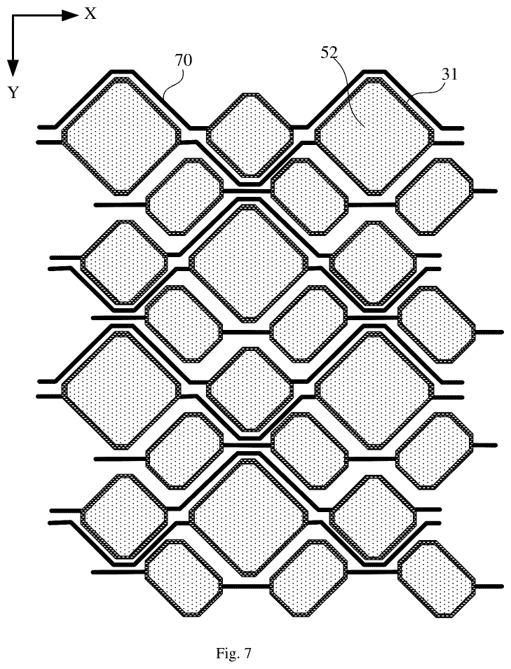

In some optional embodiments, as shown in FIG. 8, the display panel may further include a plurality of power buses 80, the second electrodes of the light-emitting devices of the same color may be connected to the same power bus, and the second electrodes of the light-emitting devices of different colors may be connected to different power buses. The second electrodes of all the light-emitting devices of the same color in the display panel may be connected to the same power bus. As an example, the potentials of the signals transmitted by different power buses may be set differently according to the actual display situation.

As an example, the display panel may include a display region AA and a non-display region NA. The non-display region NA may encircle the display region AA. The non-display region NA may include a binding region BA. The light-emitting devices are distributed in the display region AA. The power bus 80 may be located in the non-display region NA. The power bus 80 may extend to the binding region BA and be connected to a binding terminal of the binding region BA.

By providing the connection bus, it is possible to provide the required drive signals to the second electrodes of the light-emitting devices of each color respectively. For example, it is possible to provide the signals of different potentials to the second electrodes of the light-emitting devices of different colors.

As an example, the connection line 70 connecting the second electrodes of the light-emitting devices of the same color in the same row may extend in the row direction as a whole. As an example, the connection line 70 and the conductive unit 31 may be located in the same film layer. In order to avoid any connection between the second electrodes of the light-emitting devices of different colors, the first connection line 71 may have a bypassing line segment.

Similarly, FIG. 8 illustrates three types of second electrodes 52 of roughly the same shape but different areas. It can be understood that FIG. 8 illustrates the light-emitting devices 50 of three colors. The amount of power buses 80 may be three, and the second electrodes of the light-emitting devices 50 of three colors are connected to the three power buses in one-to-one correspondence.

Taking FIG. 8 as an example, the light-emitting devices 50 may include a first light-emitting device 501, a second light-emitting device 502 and a third light-emitting device 503 emitting light of different colors. For example, the first light-emitting device 501 can emit red light, the second light-emitting device 502 can emit green light, and the third light-emitting device 503 can emit blue light. The power bus 80 may include a first power bus 81, a second power bus 82 and a third power bus 83.

In order to clearly distinguish the second electrodes of different light-emitting devices, the second electrode 52 of the first light-emitting device 501 is referred to as a first sub-electrode 521, the second electrode 52 of the second light-emitting device 502 is referred to as a second sub-electrode 522, and the second electrode 52 of the third light-emitting device 503 is referred to as a third sub-electrode 523. The first sub-electrode 521 may be connected to the first power bus 81, the second sub-electrode 522 may be connected to the second power bus 82, and the third sub-electrode 523 may be connected to the third power bus 83.

As an example, all the first sub-electrodes 521 in the display panel may be connected to the first power bus 81, all the second sub-electrodes 522 in the display panel may be connected to the second power bus 82, and all the third sub-electrodes 523 in the display panel may be connected to the third power bus 83.

Continuing to refer to FIG. 8, both sides in the row direction X of the non-display region NA may be provided with the first power bus 81, the second power bus 82 and the third power bus 83. The first power buses 81 of the non-display regions NA on the two sides in the row direction X may be connected to different binding terminals, the second power buses 82 of the non-display regions NA on the two sides in the row direction X may be connected to different binding terminals, and the third power buses 83 of the non-display regions NA on the two sides in the row direction X may be connected to different binding terminals.

For example, each of the first power bus 81, the second power bus 82 and the third power bus 83 may at least partially encircle the display region AA. The second electrodes 521 of the first light-emitting devices 501 in the same row are connected to the first power buses 81 on both sides, the second electrodes 522 of the second light-emitting devices 502 in the same row are connected to the second power buses 82 on both sides, and the second electrodes 523 of the third light-emitting devices 503 in the same row are connected to the third power buses 83 on both sides. In this way, it is possible to provide drive signals to the second electrodes in the same row from both ends, so as to improve the problem of uneven display caused by voltage drop and signal delay.

FIG. 9 shows yet another schematic top view of a local region of a display panel provided by an embodiment of the application. In some optional embodiments, as shown in FIG. 9, both the first power bus 81 and the third power bus 83 may extend in a column direction Y, and one of the first power bus and the third power bus is located on a side of the display panel in a row direction X and the other is located on the other side of the display panel in the row direction X. The second power bus 82 may extend in the row direction X and is located on a side of the display panel in the column direction Y. Each of the first power bus 81, the second power bus 82 and the third power bus 83 may extend to the binding region BA and be connected to the binding terminal of the binding region BA.

Since only one power bus is provide on each side, the line width of the power wiring may be set larger to reduce voltage drop and improve display uniformity.

Continuing to refer to FIG. 9, the connection line 70 may include a first connection line 71 and a second connection line 72, and the first connection line 71 intersects with an extension direction of the second connection line 72. In the case that the second electrodes 52 of the light-emitting devices of the same color in the same row are connected by the first connection line 71, the second electrodes 52 of the light-emitting devices of the same color in the same column for at least one color are connected by the second connection line 72; or in the case that the second electrodes 52 of the light-emitting devices of the same color in the same column are connected by the first connection line 71, the second electrodes 52 of the light-emitting devices of the same color in the same row for at least one color are connected by the second connection line 72.

All the drawings of the application take the second electrodes 52 of the light-emitting devices of the same color in the same row connected by the first connection line 71 as an example, which is not used to limit the application. In the application, since the extension directions of the first connection line 71 and the second connection line 72 intersect with each other, the first connection line 71 and the second connection line 72 corresponding to the light-emitting devices of the same color form a grid shape, which can reduce the voltage drop of the connection line and improve display uniformity.

For example, in order to better distinguish the first connection lines connecting the light-emitting devices of different colors, the first connection line 71 connecting the first sub-electrodes 521 is referred to as a first sub-connection line 711, the first connection line 71 connecting the second sub-electrodes 522 is referred to as a second sub-connection line 712, and the first connection line 71 connecting the third sub-electrodes 523 is referred to as a third sub-connection line 713. Each of the first sub-connection line 711, the second sub-connection line 712 and the third sub-connection line 713 may extend in the row direction X. The first sub-connection line 711 is connected to the first power bus 81, the second sub-connection line 712 is connected to the second power bus 82, and the third sub-connection line 713 is connected to the third power bus 83.

The second connection line 72 may extend in the column direction Y.

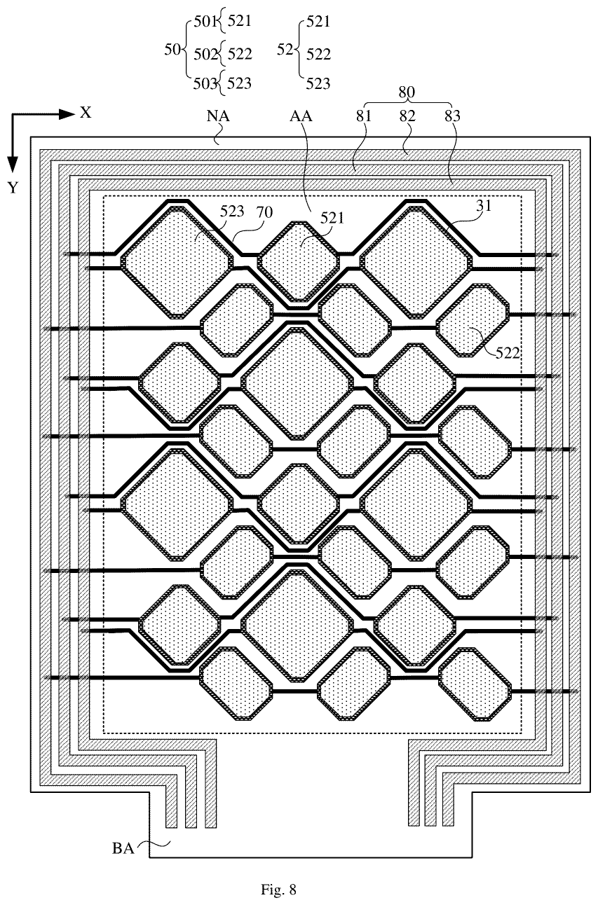

As shown in FIGS. 9 and 10, in order to clearly illustrate the second connection line 72, FIG. 10 only illustrates a partial structure corresponding to the second light-emitting devices 502, and the second electrodes 522 of the second light-emitting devices 502 in the same column may be connected by the second connection line. The second light-emitting devices 502 may emit green light. Since human eyes are relatively sensitive to green, the total amount of the second light-emitting devices 502 may be greater than the total amount of the first light-emitting devices 501, and the total amount of the second light-emitting devices 502 may be greater than the total amount of the third light-emitting devices 503. The more the amount of second light-emitting devices 502 is, the denser the mesh holes formed by the second sub-connection lines 712 and the second connection lines 72 are, which can further reduce the voltage drop of the connection lines.

In some optional embodiments, since the extension directions of the first connection line 71 and the second connection line 72 intersect with each other, in order to avoid signal crosstalk, the first connection line 71 and the second connection line 72 may be at least partially located in different film layers.

As an example, the first connection lines 71 corresponding to the first light-emitting devices 501 and the third light-emitting devices 502 may be located in the same film layer. The first connection line 71 and the second connection line 72 corresponding to the second light-emitting devices 502 are located in the same film layer, and the second connection line 72 is located in a different film layer from the first connection line 71 corresponding to the first light-emitting devices 501 and the third light-emitting devices 503.

That is, the first sub-connection line 711 and the third sub-connection line 713 may be located in the same film layer, the second sub-connection line 712 and the second sub-connection line 72 may be located in the same film layer, and the second connection line 72 is located in a different film layer from the first sub-connection line 711 and the third sub-connection line 713, and the second sub-connection line 712 is located in a different film layer from the first sub-connection line 711 and the third sub-connection line 713.

For example, the first sub-connection line 711 and the third sub-connection line 703 may be arranged within the drive substrate 10. The first sub-connection line 711 may be connected to the conductive unit 31 corresponding to the first light-emitting devices 501 via a first via hole h1, and the third sub-connection line 703 may be connected to the conductive unit 31 corresponding to the third light-emitting devices 503 via a third via hole h3.

As an example, the second sub-connection line 712 and the second connection line 72 may be located in the same film layer as the conductive unit 31, so that the second sub-connection line 712 and the second connection line 72 can be directly connected to the conductive unit 31 corresponding to the second light-emitting devices 502. At least one of the second sub-connection line 712, the second connection line 72 and the conductive unit 31 corresponding to the second light-emitting devices 502 may be connected to the second power bus via a second via hole h2.

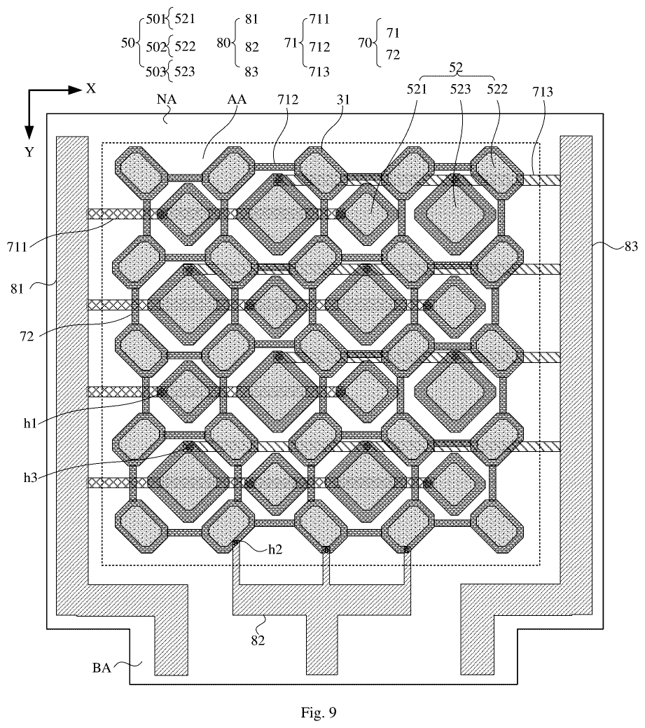

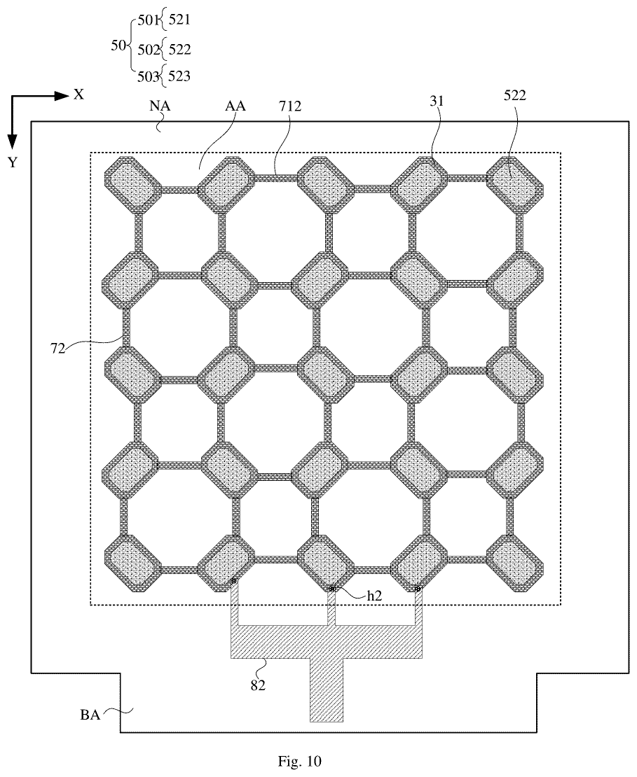

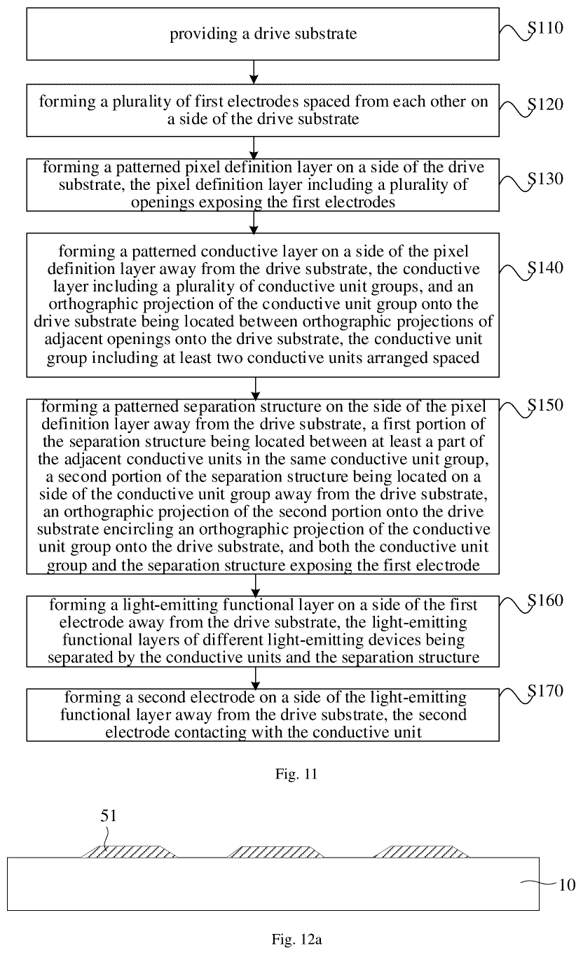

Based on the same inventive concept, the application also provides a manufacturing method of a display panel. As shown in FIG. 11, the manufacturing method of a display panel may include the steps of S110˜S140 and S160˜S170.

S110, providing a drive substrate;

S120, forming a plurality of first electrodes spaced from each other on a side of the drive substrate;

S130, forming a patterned pixel definition layer on a side of the drive substrate, the pixel definition layer including a plurality of openings exposing the first electrodes;

S140, forming a patterned conductive layer on a side of the pixel definition layer away from the drive substrate, the conductive layer including a plurality of conductive unit groups, and an orthographic projection of the conductive unit group onto the drive substrate being located between orthographic projections of adjacent openings onto the drive substrate, the conductive unit group including at least two conductive units arranged spaced;

S160, forming a light-emitting functional layer on a side of the first electrode away from the drive substrate, the light-emitting functional layers of different light-emitting devices being separated by the conductive units and the separation structure;

S170, forming a second electrode on a side of the light-emitting functional layer away from the drive substrate, the second electrode contacting with the conductive unit.

In the manufacturing method of a display panel provided by the embodiments of the application, the second electrode contacts with the conductive unit, so that a drive signal can be supplied to each second electrode by the conductive unit, thereby achieving the driving of the second electrode easily.

In some embodiments, as shown in FIG. 11, after S140 and before S160, the method provided by the embodiments of the application may further include S150.

S150, forming a patterned separation structure on the side of the pixel definition layer away from the drive substrate, a first portion of the separation structure being located between at least a part of the adjacent conductive units in the same conductive unit group, a second portion of the separation structure being located on a side of the conductive unit group away from the drive substrate, an orthographic projection of the second portion onto the drive substrate covering an orthographic projection of the conductive unit group onto the drive substrate, and both the conductive unit group and the separation structure exposing the first electrode.

According to the embodiments of the application, since the orthographic projection of the second portion onto the drive substrate covers the orthographic projection of the conductive unit group onto the drive substrate, then the side surface consisting of the second portion and the conductive unit group as a whole is not a flat surface, and in the direction parallel to the light-emitting surface of the display panel, the side surface of the conductive unit group is closer to the first portion than the side surface of the second portion, so that true physical insulation can be achieved between the light-emitting functional layers of different light-emitting devices and the lateral leakage between different light-emitting devices is reduced, thereby improving the display effect. In addition, the second electrodes of different light-emitting devices are separated from each other, which is conducive to providing different drive signals to the second electrodes of different light-emitting devices, thereby facilitating dynamic adjustment of the potentials of different second electrodes, so that the power consumption of the display panel can be reduced.

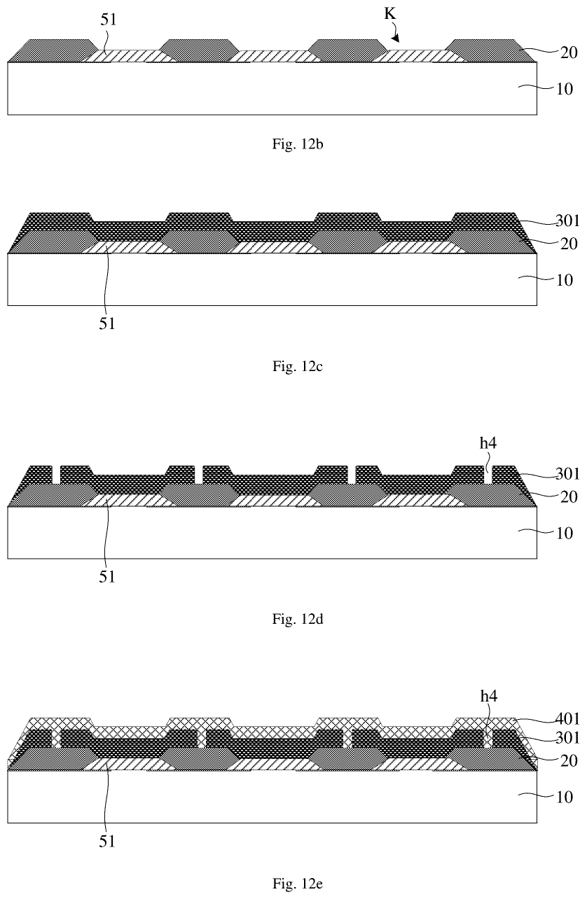

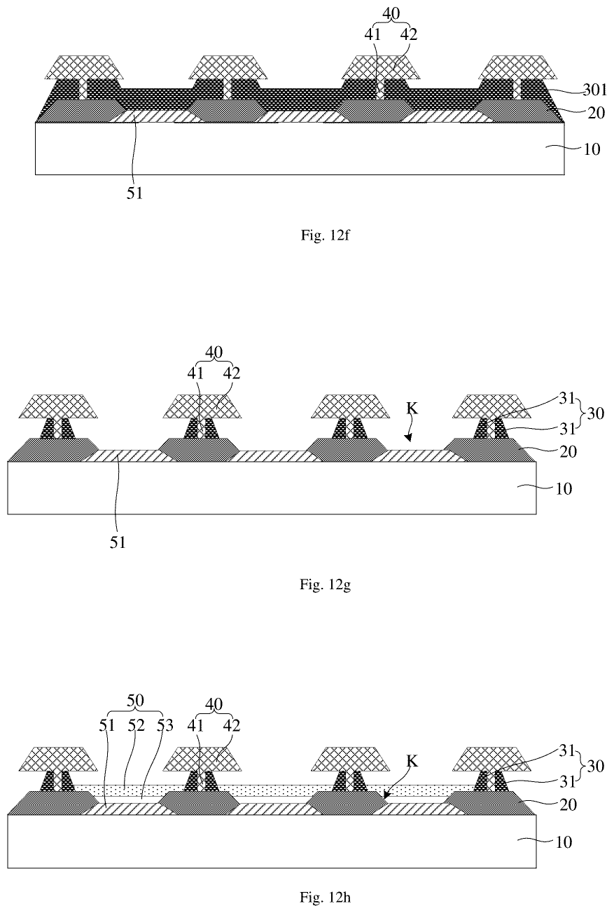

As an example, the semi-finished or finished structures of the display panels corresponding to S110 to S170 may be shown in FIGS. 12a to 12h.

In S120, as shown in FIG. 12a, a plurality of separated first electrodes 51 may be formed on a side of the drive substrate 10.

In S130, as shown in FIG. 12b, a patterned pixel definition layer 20 may be formed on the side where the first electrode 51 is located, the opening K can expose the first electrode 51, and the pixel definition layer 20 can cover a part of the edge of the first electrode 51.

In S140 and S150, referring to FIGS. 12c to 12g, as shown in FIG. 12c, a metal material may be deposited as a whole to form a first body layer 301, and the first body layer 301 can cover the pixel definition layer 20 and the first electrode 51.

Next, as shown in FIG. 12d, the first body layer 301 may be patterned to form a plurality of via holes h4, and the via holes h4 overlap with the pixel definition layer 20 and run through the first body layer 301.

Next, as shown in FIG. 12e, an insulating material may be deposited as a whole using chemical vapor deposition (CVD) to form a second body layer 401, the second body layer 401 covers the first body layer 301, and the via holes h4 are also filled with a part of the second body layer 401.

Next, as shown in FIG. 12f, the second body layer 401 may be patterned, the portion above the first electrodes 51 is removed and the portion above the pixel definition layer 20 is retained, so as to obtain the separation structure 40. Here the portion filled in the via holes h4 is the first portion 41 of the separation structure 40, and the portion above the first body layer 301 is the second portion 42 of the separation structure 40.

Next, as shown in FIG. 12g, the first body layer 301 may be patterned again, for example, by using wet etching to remove the portion on the first electrodes 51 to obtain a plurality of conductive units 31, so that the orthographic projection of the second portion 42 onto the drive substrate 10 covers the orthographic projection of the conductive unit 31 onto the drive substrate 10.

In S160 and S170, as shown in FIG. 12h, the light-emitting functional layer 53 may be evaporation coated at first, and then the second electrodes 52 may be evaporation coated. The evaporation coating angle can be controlled in such a way that the second electrodes 52 contact with the conductive units 31.

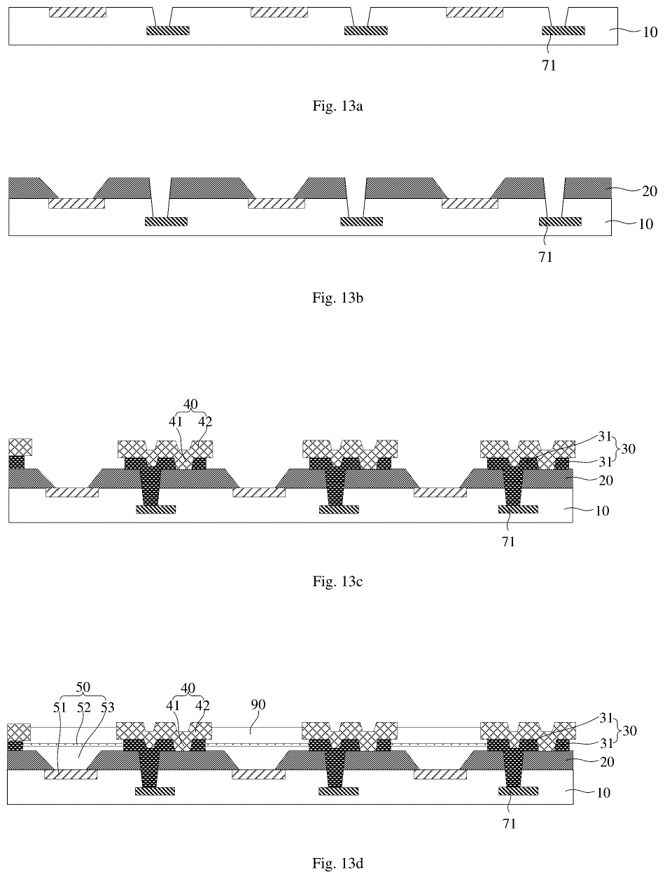

In some optional embodiments, in S110, as shown in FIG. 13a, the drive substrate 10 as provided may include a first connection line 71. The drive substrate 10 may reserve a via hole exposing at least some segments of the first connection line 71.

In S130, as shown in FIG. 13b, a patterned pixel definition layer 20 may be formed on the side where the first electrode 51 is located, the opening K can expose the first electrode 51, and a via hole may be made in the pixel definition layer 20 exposing at least some segments of the first connection line 71.

In S140 and S150, referring to FIG. 13c, a conductive layer 30 and a separation structure 40 may be formed sequentially. The conductive layer 30 includes a plurality of conductive units 31 connected to the first connection line 71 by a reserved via hole. The adjacent conductive units 31 are directly separated by the separation structure 40.

In S160 and S170, as shown in FIG. 13d, a light-emitting functional layer 53 and a second electrode 52 may be formed sequentially.

As shown in FIG. 13d, the second electrode 52 can be covered with an insulation layer 90. The insulation layer 90 may be an inorganic layer and may serve as a packaging film layer for the light-emitting device.

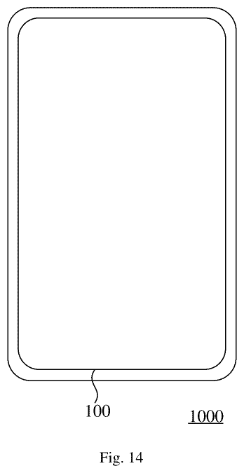

The application further provides a display apparatus including the display panel provided by the application. Referring to FIG. 14, FIG. 14 is a schematic structural view of a display apparatus provided by an embodiment of the application. The display device 1000 as provided in FIG. 14 includes the display panel 100 provided by any of the aforesaid embodiments of the application. The embodiment in FIG. 14 only takes the mobile phone as an example to illustrate the display apparatus 1000. It can be understood that the display apparatus provided by the embodiments of the application may be another display apparatus with display function such as a wearable product, a computer, a television, a car mounted display apparatus and the like, which is not limited specifically by the application. The display apparatus provided by the embodiments of the application has the beneficial effects of the display panel provided by the embodiments of the application. For details, please refer to the specific explanations of the display panels in the above various embodiments, which will not be repeated here by the application.

In accordance with the embodiments of the application as described above, these embodiments are not intended to be exhaustively set forth all the details, nor are they intended to limit the application to the specific embodiments described. It will be apparent that many modifications and variations are possible from the above description. These embodiments have been chosen and described in detail in the description in order to better explain the principle and practical application of the application, thereby enabling a person skilled in the art to make better use of the application and its modifications. The application is limited only by the claims and their full scope and equivalents.

What is claimed is:

1. A display panel comprising:
a drive substrate;
a pixel definition layer located on a side of the drive substrate, the pixel definition layer comprising a plurality of openings;
a conductive layer located on a side of the pixel definition layer away from the drive substrate, the conductive layer comprising a plurality of conductive unit groups, and an orthographic projection of the conductive unit group onto the drive substrate being located between orthographic projections of adjacent openings onto the drive substrate, the conductive unit group comprising at least two conductive units arranged spaced;
a plurality of light-emitting devices arranged in the plurality of openings respectively, each of the plurality of light-emitting devices comprising a first electrode, a light-emitting functional layer and a second electrode sequentially stacked in a direction away from the drive substrate, the second electrode contacting with the conductive unit.

2. The display panel according to claim 1, wherein the display panel further comprises:
a separation structure comprising a first portion and a second portion connected to each other, the first portion being located between at least a part of the adjacent conductive units in the same conductive unit group, the second portion being located on a side of the conductive unit group away from the drive substrate, an orthographic projection of the second portion onto the drive substrate covering an orthographic projection of the conductive unit group onto the drive substrate, and the separation structure being an insulation structure.

3. The display panel according to claim 1, wherein the display panel further comprises:
a connection line connected to the conductive unit, the second electrode of at least a part of the plurality of light-emitting devices being connected to the conductive unit by the connection line.

4. The display panel according to claim 1, wherein
the conductive units are in one-to-one correspondence with the openings.

5. The display panel according to claim 3, wherein the connection line is located on the same film layer as the conductive unit, or the connection line is arranged in the drive substrate.

6. The display panel according to claim 3, wherein a display region of the display panel comprises a plurality of sub-display regions, and the second electrodes of the light-emitting devices in the same sub-display region are connected by the connection line.

7. The display panel according to claim 6, wherein the display panel further comprises a plurality of power buses, the second electrodes of the light-emitting devices in the same sub-display region are connected to the same power bus, and the second electrodes of the light-emitting devices in different sub-display regions are connected to different power buses.

8. The display panel according to claim 3, wherein the plurality of light-emitting devices comprises the light-emitting devices of a plurality of colors in the display region of the display panel, and the second electrodes of the light-emitting devices of the same color are connected by the connection line.

9. The display panel according to claim 8, wherein the plurality of light-emitting devices are arranged in a plurality of rows, and the second electrodes of the light-emitting devices of the same color in the same row or the same column are connected by the connection line.

10. The display panel according to claim 8, wherein the display panel further comprises a plurality of power buses, the second electrodes of the light-emitting devices of the same color are connected to the same power bus, and the second electrodes of the light-emitting devices of different colors are connected to different power buses.

11. The display panel according to claim 8, wherein the connection line comprises a first connection line and a second connection line, and the first connection line intersects with an extension direction of the second connection line;
the second electrodes of the light-emitting devices of the same color in the same row are connected by the first connection line, and the second electrodes of the light-emitting devices of the same color in the same column for at least one color are connected by the second connection line; or
the second electrodes of the light-emitting devices of the same color in the same column are connected by the first connection line, and the second electrodes of the light-emitting devices of the same color in the same row for at least one color are connected by the second connection line.

12. The display panel according to claim 11, wherein the plurality of light-emitting devices comprises first light-emitting devices emitting red light, second light-emitting devices emitting green light and third light-emitting devices emitting blue light, and the second electrodes of the second light-emitting devices in the same column are connected to each other by the second connection line.

13. The display panel according to claim 11, wherein at least a part of the first connection lines and at least a part of the second connection lines are located in different film layers.

14. The display panel according to claim 12, wherein the first connection line corresponding to the first light-emitting devices and the first connection line corresponding to the third light-emitting devices are located in the same film layer, the first connection line corresponding to the second light-emitting devices and the second connection line corresponding to the second light-emitting devices are located in the same film layer, and the second connection line corresponding to the second light-emitting devices and the first connection line corresponding to the first light-emitting devices are located in different film layers, and the second connection line corresponding to the second light-emitting devices and the first connection line corresponding to the third light-emitting devices are located in different film layers.

15. The display panel according to claim 13, wherein the first connection line and the second connection line corresponding to the second light-emitting devices are located in the same film layer as the conductive units.

16. The display panel according to claim 8, wherein the display panel comprises a non-display region and a display region, the power buses comprises a first power bus, a second power bus and a third power bus located in the non-display region, the plurality of light-emitting devices comprises first light-emitting devices, second light-emitting devices and third light-emitting devices emitting light of different colors, the second electrodes of the first light-emitting devices are connected to the first power bus, the second electrodes of the second light-emitting devices are connected to the second power bus, and the second electrodes of the third light-emitting devices are connected to the third power bus;
both the first power bus and the third power bus extend in a column direction, one of the first power bus and the third power bus is located on a side of the display panel in a row direction and the other is located on the other side of the display panel in the row direction, and the second power bus extends in the row direction and is located on a side of the display panel in the column direction;
or, the first power bus, the second power bus and the third power bus are located on each of two sides of the display panel in the row direction, the second electrodes of the first light-emitting devices in the same row are connected to the first power buses on both sides, the second electrodes of the second light-emitting devices in the same row are connected to the second power buses on both sides, and the second electrodes of the third light-emitting devices in the same row are connected to the third power buses on both sides.

17. The display panel according to claim 3, wherein any two adjacent conductive units are connected with the connection line.

18. A manufacturing method of a display panel, comprising:
providing a drive substrate;
forming a plurality of first electrodes spaced from each other on a side of the drive substrate;
forming a patterned pixel definition layer on a side of the drive substrate, the pixel definition layer comprising a plurality of openings exposing the first electrodes;
forming a patterned conductive layer on a side of the pixel definition layer away from the drive substrate, the conductive layer comprising a plurality of conductive unit groups, and an orthographic projection of the conductive unit group onto the drive substrate being located between orthographic projections of adjacent openings onto the drive substrate, the conductive unit group comprising at least two conductive units arranged spaced;
forming a light-emitting functional layer on a side of the first electrode away from the drive substrate, the light-emitting functional layers of different light-emitting devices being separated by the conductive units and the separation structure;
forming a second electrode on a side of the light-emitting functional layer away from the drive substrate, the second electrode contacting with the conductive unit.

19. The method according to claim 18, wherein, after forming the conductive layer and before forming the light-emitting functional layer, the method further comprises:
forming a patterned separation structure on the side of the pixel definition layer away from the drive substrate, a first portion of the separation structure being located between at least a part of the adjacent conductive units in the same conductive unit group, a second portion of the separation structure being located on a side of the conductive unit group away from the drive substrate, an orthographic projection of the second portion onto the drive substrate covering an orthographic projection of the conductive unit group onto the drive substrate, and both the conductive unit group and the separation structure exposing the first electrode.

20. A display apparatus comprising the display panel according to claim 1.
